(19) United States
(12) Patent Application Publication
(10) Pub. No.: US 2026/0172002 A1
(43) Pub. Date: Jun. 18, 2026

(54) MULTI-STACK ACOUSTIC WAVE DEVICE

(71) Applicant: SKYWORKS SOLUTIONS, INC., Irvine, CA (US)

(72) Inventor: Howard E. Chen, Anaheim, CA (US)

(21) Appl. No.: 19/407,074

(22) Filed: Dec. 3, 2025

Related U.S. Application Data
(60) Provisional application No. 63/733,210, filed on Dec. 12, 2024.
(60) Provisional application No. 63/766,648, filed on Mar. 4, 2025.

(51) Int. Cl. H03H 9/13; H03H 9/54

(52) U.S. Cl. CPC H03H 9/133; H03H 9/54

(57) ABSTRACT

A multi-stack acoustic wave device is provided that comprises a substrate, a first die having a first portion having one or more electrodes and a second portion positioned away from the first portion, the one or more electrodes of the first die being electrically connected with one or more electrodes of the substrate, a second die having a first portion having one or more electrodes and a second portion positioned away from the first portion, the first die being positioned between the second die and the substrate, the second portion of the first die being coupled to the second portion of the second die, and a packaging structure encapsulating at least a portion of the second die and having one or more electrodes positioned away from the substrate, the one or more electrodes of the second die being electrically connected to the one or more electrodes of the packaging structure.

### CROSS-REFERENCE TO RELATED APPLICATIONS

This application claims priority under 35 U.S.C. § 119(e) to U.S. Provisional Patent Application Ser. No. 63/766,648, titled “MULTI-STACK ACOUSTIC WAVE DEVICE”, filed Mar. 4, 2025, and to U.S. Provisional Patent Application Ser. No. 63/733,210, titled “FILTER FLIP STACK GROUND PATH METHODS”, filed Dec. 12, 2024, the entire content of each being incorporated herein by reference for all purposes.

### BACKGROUND

### Field

The present disclosure generally relates to acoustic wave devices and manufacturing method thereof, and particularly to multi-stack dies and multi-chip modules comprising such multi-stack dies and manufacturing method thereof.

### Description of Related Art

Acoustic wave devices, such as those used in radio frequency (RF) front-end modules, face increasing demands for miniaturization with each new product generation. While maintaining the same functionality, a reduction in the X-Y dimensions of such modules is may accommodate evolving product design requirements. Typically, with each new generation, module areas are expected to reduce by approximately 10-15%, creating more space in compact module surface areas.

However, this reduction in module size is constrained by physical X-Y spacing rules, particularly in relation to the placement of filters and surface-mount technology (SMT) components, which are typically positioned side by side. As a result, there is a significant challenge in maintaining the same number of components, such as silicon dies, acoustic filters, and SMT components, within a smaller package area.

Existing solutions typically involve adopting alternative architectures that reduce the number of components within the module. While this approach may achieve the necessary size reduction, it tends to compromise the functionality and performance of the components and the module due to scaling issues or the elimination of existing components. This trade-off may be particularly problematic in RF front-end modules, where maintaining a full set of components is important for ensuring the module's ability to handle multiple frequency bands and signal processing functions.

Accordingly, there is a need for an improved packaging solution that allows the same number of silicon dies, acoustic filters, and SMT components to be accommodated in a smaller package area without sacrificing functionality or performance.

### SUMMARY

In accordance with one aspect, there is provided a multi-stack acoustic wave device. The multi-stack acoustic wave device comprises a substrate having one or more electrodes, a first die having a first portion having one or more electrodes and a second portion positioned away from the first portion, the one or more electrodes of the first die being coupled to and electrically connected with the one or more electrodes of the substrate, a second die having a first portion having one or more electrodes and a second portion positioned away from the first portion, the first die being positioned between the second die and the substrate, and the second portion of the first die being coupled to the second portion of the second die, and a packaging structure encapsulating at least a portion of the second die, the packaging structure having one or more electrodes positioned away from the substrate, the one or more electrodes of the second die being electrically connected to the one or more electrodes of the packaging structure via one or more electrical connections.

In some embodiments, the one or more electrical connections electrically connecting the one or more electrodes of the second die to the one or more electrodes of the packaging structure are provided in form(s) of bonding wire(s).

In some embodiments, the one or more electrical connections electrically connecting the one or more electrodes of the second die to the one or more electrodes of the packaging structure are provided in form(s) of via(s).

In some embodiments, the one or more electrical connections electrically connecting the one or more electrodes of the second die to the one or more electrodes of the packaging structure are provided in form(s) of conductive wall(s), wire(s), rod(s), and/or bar(s).

In some embodiments, the one or more electrodes of the first die are directly coupled to the one or more electrodes of the substrate.

In some embodiments, the one or more electrodes of the first die are coupled to the one or more electrodes of the substrate via one or more conductive layers.

In some embodiments, the one or more electrodes of the first die are coupled to the one or more electrodes of the substrate via one or more bonding layers.

In some embodiments, the one or more electrodes of the first die comprise a portion that is at least partially embedded in the first portion of the first die.

In some embodiments, the one or more electrodes of the first die comprise a portion that is formed on a surface of the first portion of the first die.

In some embodiments, the one or more electrodes of the first die comprise a portion extending through a thickness of the first portion of the first die forming an electrical path connecting to the second portion of the first die.

In some embodiments, the one or more electrodes of the first die comprise a via extending through a thickness of the first portion of the first die forming an electrical path connecting to the second portion of the first die.

In some embodiments, the first die is an acoustic wave filter.

In some embodiments, the first die is a multi-layer piezoelectric substrate acoustic wave filter.

In some embodiments, the one or more electrodes of the second die are electrically connected with the one or more electrodes of the packaging structure via one or more bonding wires formed using forward bonding techniques.

In some embodiments, the one or more electrodes of the second die are electrically connected with the one or more electrodes of the packaging structure via one or more bonding wires formed using reverse bonding techniques.

In some embodiments, the one or more electrodes of the second die comprise a portion that is at least partially embedded in the first portion of the second die.

In some embodiments, the one or more electrodes of the second die comprise a portion that is formed on a surface of the first portion of the second die.

In some embodiments, the one or more electrodes of the second die comprise a portion extending through a thickness of the first portion of the second die forming an electrical path connecting to the second portion of the second die.

In some embodiments, the one or more electrodes of the second die comprise a via extending through a thickness of the first portion of the second die forming an electrical path connecting to the second portion of the second die.

In some embodiments, the one or more electrodes of the second die are positioned between the first portion and the second portion of the second die.

In some embodiments, the second die is an acoustic wave filter.

In some embodiments, the second die is an integrated passive device.

In some embodiments, the second die is a multi-layer piezoelectric substrate acoustic wave filter.

In some embodiments, the second portion of the first die is coupled to the second portion of the second die via a bonding layer.

In some embodiments, the second portion of the first die is coupled to the second portion of the second die via a die attach film.

In some embodiments, the substrate is a laminate substrate.

In some embodiments, the substrate is a printed circuit board.

In some embodiments, the substrate is a ceramic substrate.

In some embodiments, the substrate is a multi-chip module.

In some embodiments, the substrate is a deposited multi-chip module.

In some embodiments, the one or more electrodes are connected to one or more electrical connections within the substrate.

In some embodiments, the one or more electrodes of the packaging structure are connected to one or more electrical connections within the packaging structure.

In accordance with another aspect, there is provided a radio-frequency module comprising a multi-stack acoustic wave device having a substrate having one or more electrodes, a first die having a first portion having one or more electrodes and a second portion positioned away from the first portion, the one or more electrodes of the first die being coupled to and electrically connected with the one or more electrodes of the substrate, a second die having a first portion having one or more electrodes and a second portion positioned away from the first portion, the first die being positioned between the second die and the substrate, and the second portion of the first die being coupled to the second portion of the second die, and a packaging structure encapsulating at least a portion of the second die having one or more electrodes positioned away from the substrate, the one or more electrodes of the second die being electrically connected with the one or more electrodes of the packaging structure via one or more electrical connections.

In accordance with another aspect, there is provided a wireless mobile device. The wireless mobile device comprises one or more antennas and a radio-frequency module that communicates with the one or more antennas, the radio-frequency module including a multi-stack acoustic wave device having a substrate having one or more electrodes, a first die having a first portion having one or more electrodes and a second portion positioned away from the first portion, the one or more electrodes of the first die being coupled to and electrically connected with the one or more electrodes of the substrate, a second die having a first portion having one or more electrodes and a second portion positioned away from the first portion, the first die being positioned between the second die and the substrate, and the second portion of the first die being coupled to the second portion of the second die, and a packaging structure encapsulating at least a portion of the second die having one or more electrodes positioned away from the substrate, the one or more electrodes of the second die being electrically connected with the one or more electrodes of the packaging structure via one or more electrical connections.

### BRIEF DESCRIPTION OF THE DRAWINGS

Various aspects of at least one embodiment are discussed below with reference to the accompanying figures, which are not intended to be drawn to scale. The figures are included to provide illustration and a further understanding of the various aspects and embodiments, and are incorporated in and constitute a part of this specification, but are not intended as a definition of the limits of the aspects and embodiments disclosed herein. In the figures, each identical or nearly identical component that is illustrated in various figures is represented by a like numeral. For purposes of clarity, not every component may be labeled in every figure. In the figures:

FIG. 1 is a cross-sectional view of a known acoustic wave device comprising two dies (prior art);

FIG. 2 is a plan view of a known acoustic wave device comprising two dies (prior art);

FIG. 3A is a partial cross-sectional diagram of an exemplary acoustic wave device comprising two dies having a bond wire connection to a substrate according to an embodiment;

FIG. 3B is a cross-sectional diagram of an exemplary acoustic wave device comprising two dies having a bond wire connection to a packaging structure according to an embodiment, showing example dimensions;

FIG. 3C is a cross-sectional of an exemplary acoustic wave device comprising two dies having a bond wire connection (forward bonding) to a substrate according to an embodiment, showing example dimensions;

FIG. 3D is a cross-sectional of an exemplary acoustic wave device comprising two dies having a bond wire connection (reverse bonding) to a substrate according to an embodiment showing example dimensions;

FIG. 3E is a cross-sectional diagram of an exemplary acoustic wave device comprising two dies, with electrodes of a first die directly coupled to electrodes of a substrate, and having a bond wire connection to the substrate, according to an embodiment;

FIG. 3F is a cross-sectional diagram of an exemplary acoustic wave device comprising two dies having a bond wire connection to a substrate according to an embodiment, illustrating exemplary internal electrical connections within the two dies;

FIG. 4 is a plan view of an exemplary acoustic wave device comprising two dies according to an embodiment;

FIG. 5 is a cross-sectional view of an exemplary acoustic wave device comprising two dies according to an embodiment;

FIG. 6 is a radio-frequency front end module according to an embodiment; and

FIG. 7 is a wireless device according to an embodiment.

### DETAILED DESCRIPTION

The following detailed description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

As acoustic wave devices and modules advance, there are generally more components to be mounted on the same device and/or module, or there is a desire to decrease the planar area (e.g., “X-Y dimensions”) of the device and/or module. In particular, it is generally desirable to decrease the X-Y dimensions of RF front-end modules with each new product generation, while maintaining or enhancing their functionality. Achieving this is challenging, as it requires fitting the same number of silicon dies, acoustic wave filters, and SMT components into a smaller package.

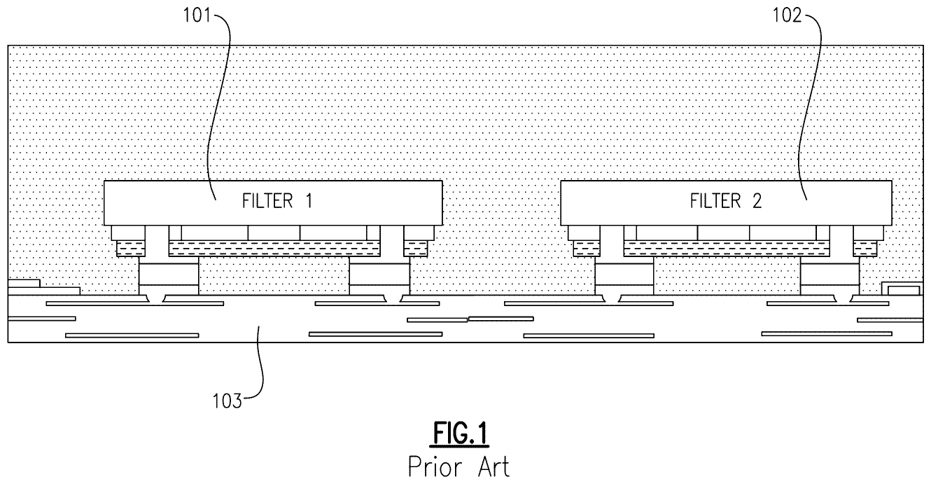

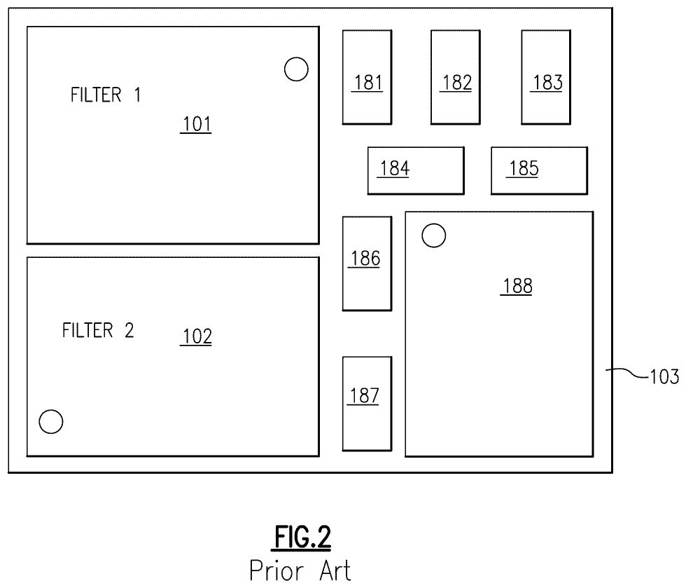

FIG. 1 illustrates a cross-section of an example acoustic wave device configured as a module, and FIG. 2 is a plan view of the example acoustic wave device. As illustrated in FIG. 1, such a module may include multiple acoustic wave components 101, 102, such as acoustic wave filters 101, 102. These components 101, 102, along with other components (e.g., electrical components) 181, 182, 183, 184, 185, 186, 187, 188, may be mounted in direct contact with the substrate 103, such as a printed circuit board (PCB). Reducing the total area occupied by these acoustic wave components 101, 102 and other components 181, 182, 183, 184, 185, 186, 187, 188 may involve either decreasing the dimensions of the components themselves or reducing their number. While this approach may decrease the planar area, it can lead to compromised performance, particularly when taking into account various scaling issues, and/or more complex substrate designs (e.g., with more intricate embedded electrical connections).

Generally, aspects and embodiments disclosed herein provide a multi-stack die comprising two or more dies. For example, the two or more dies may be stacked three-dimensionally so that one or more electrodes of only one of the dies are coupled to one or more electrodes of a substrate on which the multi-stack die is mounted. Thus, such a multi-stack die may enable better utilization of the three-dimensional spaces available above the substrate, and hence, may occupy a significantly reduced substrate area when compared to the conventional configurations such as those illustrated in FIGS. 1 and 2.

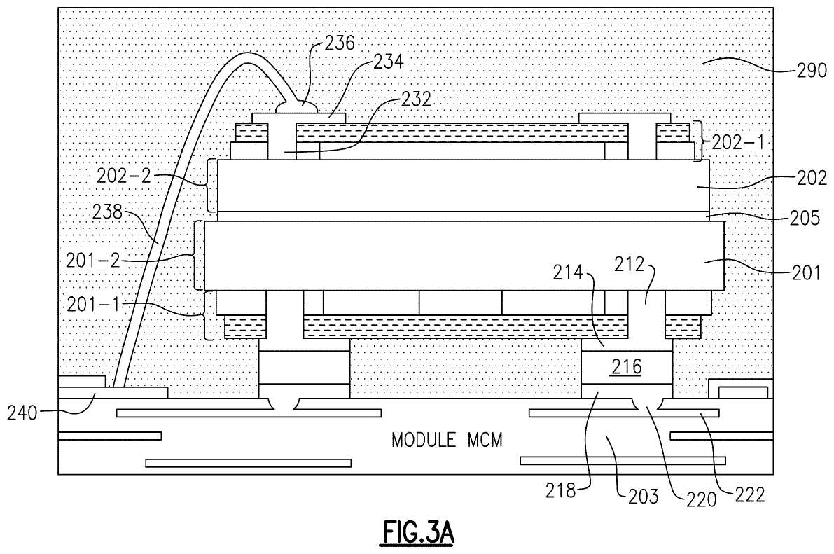

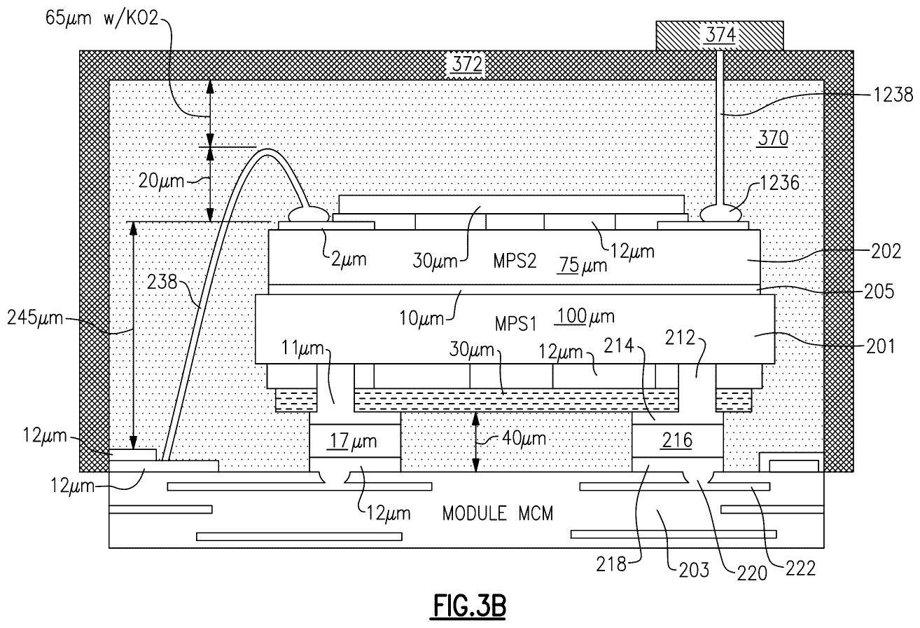

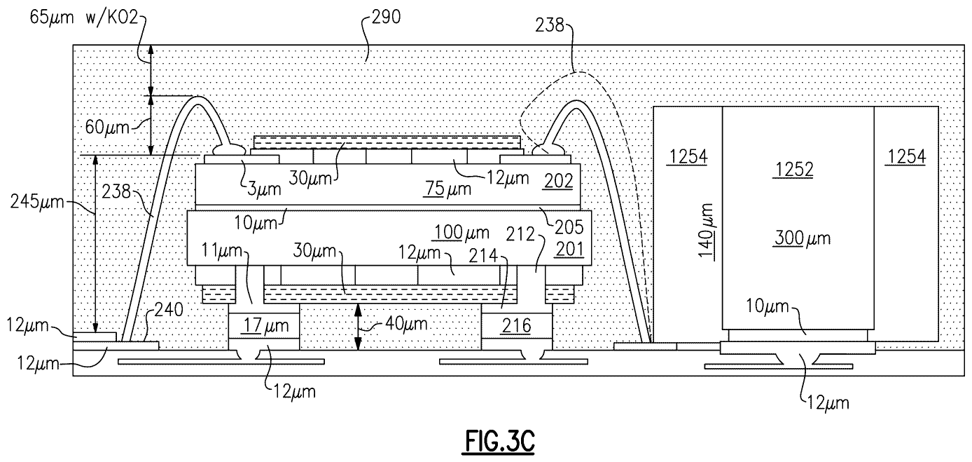

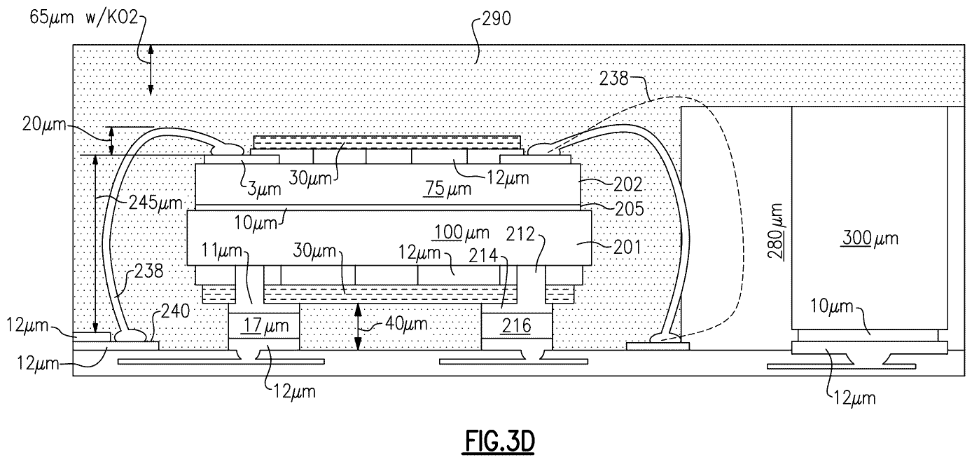

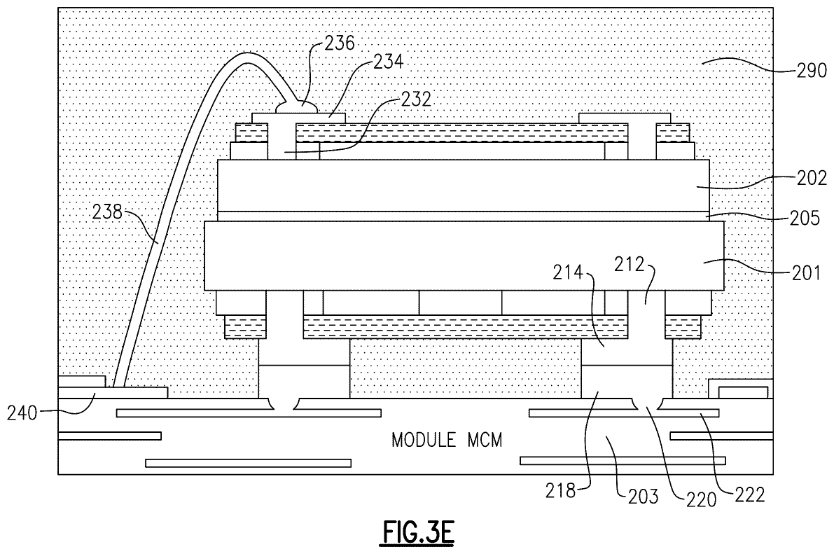

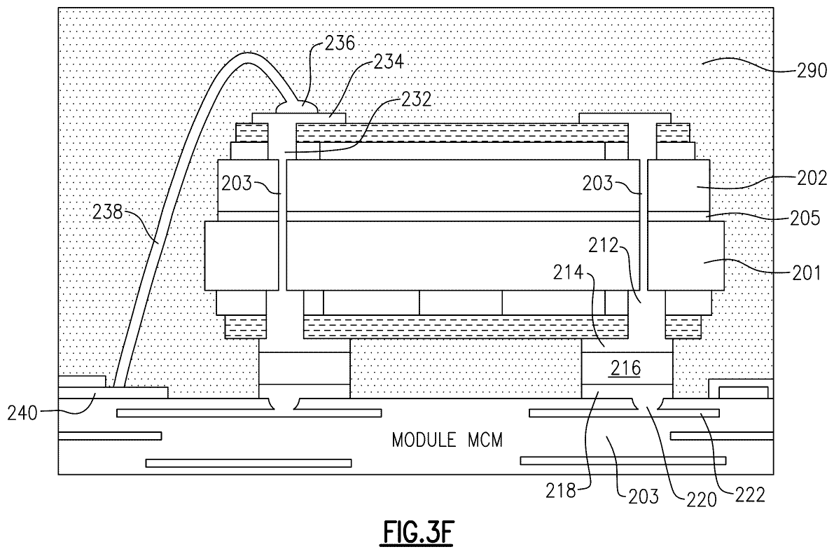

FIG. 3A shows a cross-sectional view of an exemplary acoustic wave device comprising a first die 201 and a second die 202 according to an embodiment. As shown in FIG. 3A, the two dies 201, 202 may, for example, be stacked to form a multi-stack die. Although the device in the example of FIG. 3A has two dies 201, 202, it will be appreciated that, in other embodiments, the multi-stack die may comprise more than two dies.

The first die 201 has a first portion 201-1 having one or more electrodes 212, 214 and a second portion 201-2 which is positioned away from the first portion 201-1. As shown in FIG. 3A, the first portion 201-1 of the first die 201 may be a portion comprising one or more caps and/or voids. The one or more electrodes 212, 214 of the first die 201 are configured to function as terminal(s) or contact point(s) enabling electrical connection(s) with one or more electrodes 218, 220 of a substrate 203. The one or more electrodes 212, 214 of the first die 201 may be electrically connected to the one or more electrodes 218, 220 of the substrate 203 by physical coupling. For example, as shown in FIG. 3E, the one or more electrodes 212, 214 of the first die 201 may be directly in contact with the one or more electrodes 218, 220 of the substrate 203. Alternatively, as shown in FIG. 3A, the one or more electrodes 212, 214 of the first die 201 may be coupled to the one or more electrodes 218, 220 of the substrate 203 via one or more bonding layers 216. Such a bonding layer may be conductive layer, or an adhesive layer comprising a conductive element to provide an electrical connection between the one or more electrodes 212, 214 of the first die 201 and the one or more electrodes 218, 220 of the substrate 203.

Similarly, the second die 202 has a first portion 202-1 having one or more electrodes 232, 234 and a second portion 202-2 positioned away from the first portion 202-1. As shown in FIG. 3A, the first portion 202-1 of the second die 202 may be a portion comprising one or more caps and/or voids. The one or more electrodes 232, 234 of the second die 202 are configured to function as terminal(s) or contact point(s) enabling connection(s) with one or more bonding wires 238. The one or more bonding wires 238 are configured to function as electrical connection(s) providing electrical path(s) between the one or more electrodes 232, 234 of the second die 202 and one or more electrodes 240 of the substrate 203. As shown in FIG. 3A, the substrate 203 may comprise one or more first electrodes 218, 220 for electrical connection with the one or more electrodes 212, 214 of the first die 201, and one or more second electrodes 240 for connection with the one or more bonding wires 238. The substrate 203 may comprise further electrical connections, such as redistribution layer(s) (RDLs) and/or interconnect(s) which are electrically connected to the one or more first electrodes 218, 220 and/or or more second electrodes 240.

The first die 201 is positioned between the second die 202 and the substrate 203. For example, as shown in FIG. 3A, the second die 202 may be mounted on the first die 201 in a flip-stack configuration so that the second portion 201-2 of the first die 201 is coupled to the second portion 202-2 of the second die 202. In this manner, the electrodes 212, 214 of the first die 201 and electrodes 232, 234 of the second die 202 may be placed on the opposite side of the multi-stack die. Such configurations provide spatial separation between the electrodes 212, 214 of the first die 201 and electrodes 232, 234 of the second die 202, which may be particularly advantageous for multi-chip modules with high component density.

Thus, the multi-stack die according to a number of embodiments may provide a way to use the substrate surface area more efficiently, without the needs for miniaturizing the dimensions of components mounted on the substrate surface or decreasing the number of components mounted on the substrate surface. Alternatively, the multi-stack die may also be used in conjunction with miniaturized components and/or fewer components in order to further decrease the substrate surface area occupied by the components.

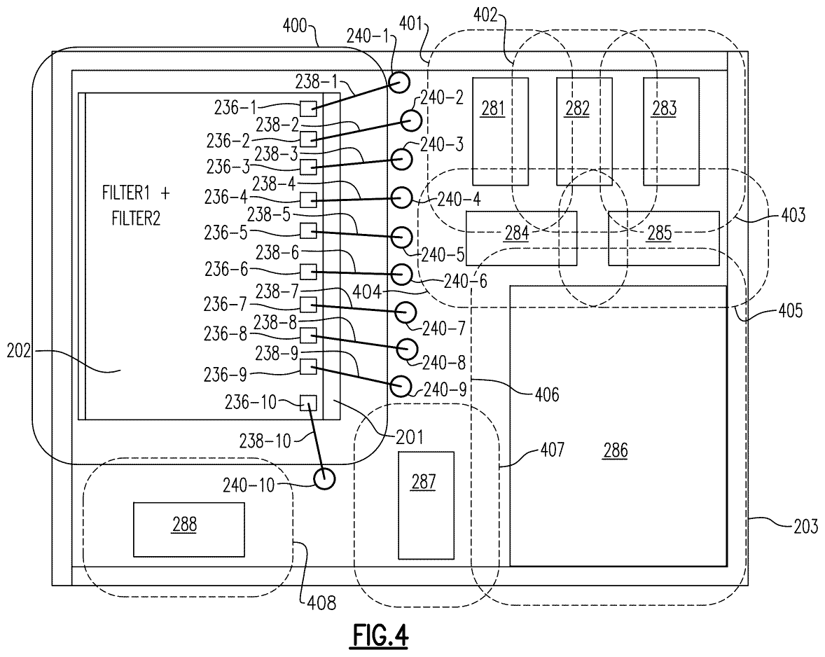

FIG. 4 shows a plan view of an exemplary acoustic wave device comprising the multi-stack die mounted on the substrate 203 with the bonding wires 238-1, 238-2, 238-3, 238-4, 238-5, 238-6, 238-7, 238-8, 238-9, 238-10 electrically connecting the electrodes 236-1, 236-2, 236-3, 236-4, 236-5, 236-6, 236-7, 236-8, 236-9, 236-10 of the second die 202 and the second electrodes 240-1, 240-2, 240-3, 240-4, 240-5, 240-6, 240-7, 240-8, 240-9, 240-10 of the substrate 203. FIG. 4 also illustrates a number of other devices 281, 282, 283, 284, 285, 286, 287, 288 that may also be mounted on the substrate 203. Areas 400, 401, 402, 403, 404, 405, 406, 407, 408 represent areas around the various devices that may be reserved for electrical connections of electrodes of the various devices to electrodes on the substrate 203. In contrast to the prior art example shown in FIG. 2, the use of the multi-stack die, as shown in FIG. 4, may lead to a significant reduction of substrate area utilized by the dies 201, 202. In the specific example of FIG. 4, ˜16 % of the X-Y area may be freed up when compared to the arrangement shown in FIG. 2, which is sufficient to offset a typical increase (e.g., 10-15%) in space requirements for each new generation of acoustic multi-chip modules.

The substrate 203 may take various forms depending on the specific design requirements and implementations. For example, the substrate 203 may be a laminate substrate, such as that used in laminated multi-chip modules (MCM-Ls). Optionally, a multi-layer laminated PCB may be employed as the substrate 203. In another embodiment, the substrate 203 may comprise a ceramic substrate, such as that used in ceramic multi-chip modules (MCM-Cs). In yet another embodiment, the substrate 203 may be a deposited multi-chip module substrate, such as that used in deposited multi-chip modules (MCM-Ds). In such implementations, the substrate 203 may be formed from a thin film deposited onto a base material. Optionally, the substrate 203 may be a MCM substrate, which may be either deposited or laminated, depending on the specific needs of the system.

FIG. 3A also illustrates a number of optional features described below. In relation to the first die 201, the one or more electrodes 212, 214 of the first die 201 may comprise or be connected to a vertical portion 212 that is at least partially embedded in the first portion 201-1 of the first die 201. The vertical portion 212 may extend through a part of the thickness of the first portion 201-1 of the first die 201. Alternatively, the vertical portion 212 may extend through or entire thickness of first portion 201-1 of the first die 201. In such embodiments, the vertical portion 212 may form an electrical path to and/or from the second portion 201-2 of the first die 201. The vertical portion 212 may be provided in the form of a via 212, such as a through-silicon via (TSV). The vertical portion 212 may optionally extend through a part of the thickness of the second portion 201-2 of the first die 201. The vertical portion 212 may be electrically connected to one or more electrical connections located within the first 201-1 and/or the second portion 201-2 of the first die 201.

Alternatively, or in conjunction with the vertical portion, the one or more electrodes 212, 214 of the first die 201 may comprise a planar portion 214 that is formed on a surface of the first portion 201-1 of the first die 201. Similarly, the planar portion 214 may be electrically connected to one or more electrical connections located within the first 201-1 and/or the second portion 201-2 of the first die 201.

Optionally, as illustrated in FIG. 3F, the one or more electrodes 212, 214 of the first die 201 and the one or more electrodes 232, 234 of the second die 202 may be electrically connected via one or more electrical connections 203. Such electrical connections 203 may, for example, be provided in forms of RDL(s), interconnect(s), via(s) and/or TSVs.

The first die 201 may be or may comprise an acoustic wave filter. For example, the first die 201 may be bulk acoustic wave filter or a surface acoustic wave filter. The first die may also comprise non-acoustic components such as electrical connections and/or components. Optionally, the acoustic components such as a resonator may located in the second portion 201-2 of the first die 201.

Alternatively, or in conjunction with the acoustic wave filter, the first die 201 may be or comprise a multi-layer piezoelectric substrate acoustic filter.

In relation to the second die 202, the one or more electrodes 232, 234 of the second die 202 may comprise or be connected to a vertical portion 232 that is at least partially embedded in the first portion 202-1 of the second die 202. The vertical portion 232 may extend through a part of the thickness of the first portion 202-1 of the second die 202. Alternatively, the vertical portion 232 may extend through or entire thickness of first portion 202-1 of the second die 202. In such implementations, the vertical portion 232 may form an electrical path to and/or from the second portion 202-2 of the second die 202. The vertical portion 232 may be provided in the form of a via 232, such as a TSV. The vertical portion 232 may optionally extend through a part of the thickness of the second portion 202-2 of the second die 202. The vertical portion 232 may be electrically connected to one or more electrical connections located within the first 202-1 and/or the second portion 202-2 of the second die 202.

Alternatively, or in conjunction with the vertical portion, the one or more electrodes 212, 214 of the second die 202 may comprise a planar portion 234 that is formed on a surface of the first portion 202-1 of the second die 202. Similarly, the planar portion 234 may be electrically connected to one or more electrical connections located within the first and/or the second portion 202-2 of the second die 202.

The one or more electrodes 232, 234 of the second die 202 may be electrically connected with the one or more second electrodes 240 of the substrate 203 via one or more bonding wires 238 formed using forward bonding techniques. Alternatively, reverse bonding techniques may be used for the wire bonding. Optionally, the wire bonding may be coupled to the planar portion 234 of the electrodes 232, 234.

The second die 202 may be or may comprise an acoustic wave filter. For example, the second die 202 may be bulk acoustic wave filter or a surface acoustic wave filter. The second die may also comprise non-acoustic components such as electrical connections and/or components. Optionally, the acoustic components such as a resonator may be located in the second portion 202-2 of the second die 202.

Alternatively, or in conjunction with the acoustic wave filter, the second die 202 may be or comprise a multi-layer piezoelectric substrate acoustic filter.

Alternatively, or in conjunction with the acoustic wave filter and/or the multi-layer piezoelectric substrate acoustic filter, the second die 202 may be or comprise an integrated passive device.

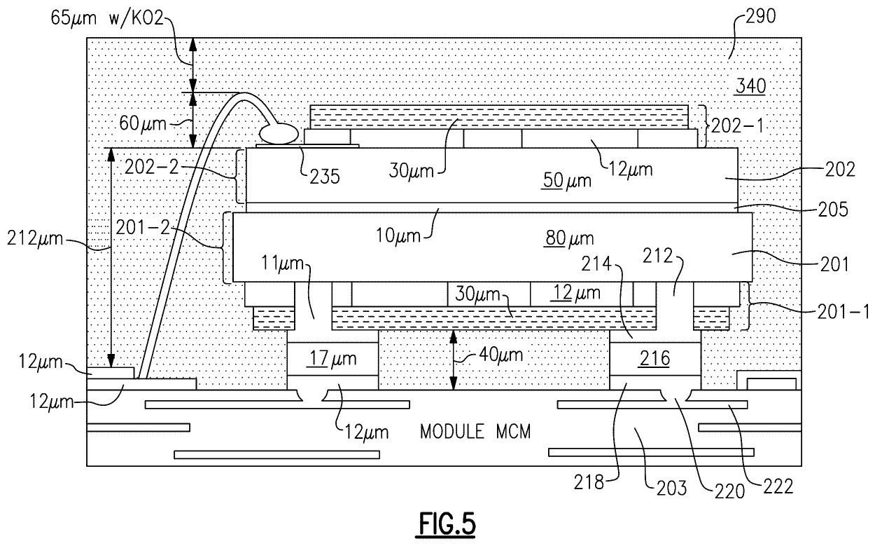

FIG. 5 illustrates an alternative embodiment of the multi-stack die and acoustic wave device. The embodiment illustrated in FIG. 5 is similar to that of FIG. 3A, except for the electrodes 232, 234 of the second die 202. As shown in FIG. 5 the one or more electrodes 235 of the second die 202 may be positioned between the first portion 202-1 and the second portion 202-2 of the second die 202. In such implementations, the one or more electrodes 235 of the second die 202 may have a first part formed on a surface of the second portion of the second die, and a second part formed between the first portion 202-1 and the second portion 202-2 of the second die 202, which enables easy wire bonding to the first part. Although the electrodes 235 of the second die 202 of the example shown in FIG. 5 only comprises a planar portion, it will be appreciated that one or more of the electrodes 235 of the second die 202 may also comprise a vertical portion as described above in relation to FIG. 3A.

FIG. 3B illustrates another alternative embodiment of the multi-stack die and acoustic wave device. The embodiment illustrated in FIG. 3B is similar to that of FIG. 3A, except that one or more of the electrodes 232, 234 of the second die 202 are electrically connected with the one or more electrodes 372, 374 of the packaging structure 290 via one or more bonding wires 1238. As shown in FIG. 3B, the one or more electrodes 374 of the of the packaging structure 290 may be formed on an outer packaging 372The outer packaging structure 372 may extend not only on top of the package, but also along the sides to encapsulate the multi-stack die, for example, to provide an electromagnetic interference (EMI) shield. It will also be appreciated that the outer packaging structure 372 may optionally encapsulate additional components beyond the multi-stack die, such as one or more acoustic and/or electronic components or devices.

If the outer packaging 372 is made of non-conductive materials, the outer packaging 372 may optionally comprise one or more electrical connections within the outer packaging which may be connected to the one or more electrodes 374. Alternatively, such an outer packaging 372 (e.g., a module shield) may be made of one or more conductive materials. In such implementations, the outer packaging 372 may be configured to function as the one or more electrodes.

Thus, the packaging structure 290, having one or more electrodes 372, 374, provides a surface or point for electrical contact on the upper surface of the packaging structure 290, which is readily accessible for further electrical connections. For example, a further electrical connection may be coupled to the electrode 374 positioned on the upper surface of the outer packaging 372. Alternatively, if the outer packaging 372 is made of one or more conductive materials, the further electrical connection may be coupled directly to the outer packaging 372 that is configured to serve as the one or more electrodes 372, in which case the electrode 374 may not be necessary. The one or more electrodes 372, 374 may be connected to ground to provide ground connection for the multi-stack die and acoustic wave device.

It will be appreciated that the dimensions (e.g. thickness, height, width values) illustrated in FIGS. 3B-3D are provided solely for illustrative purposes and are not intended to define required or exact values.

As shown in FIG. 3B, the one or more bonding wires 1238 may be coupled to the one or more of the electrodes 232, 234, 235 of the second die 202 via a bump 1236, and may extend in a direction away from the substrate 203. Although the example shown in FIG. 3B comprises one bond wire 238 (downwardly extending wire) coupled to the one or more second electrodes 240 of the substrate 203 and one bond wire 1238 (upwardly extending wire) extending in a direction away from the substrate 203, it will be appreciated that, in a number of embodiments, any suitable numbers of the downwardly extending wires (such as those explained in relation to the examples of FIG. 3A and FIG. 5) and the upwardly extending wires may be used. It will also be appreciated that, in a number of embodiments, multi-stack acoustic wave device may only comprise the upwardly extending wire(s).

Thus, in the embodiments having an upwardly extending wire, the multi-stack die is positioned between the substrate 203 and the one or more electrodes of the packaging structure 290, with an alternative electrical path 1238 that does not involve forming a wire bonding connection 238 with the one or more second electrodes 240 of the substrate 203. In such configurations, the minimum length of the upward extending wire 1238 generally depends on the thickness of the packaging structure 290 above the second die 202. Thus, the thickness of the packaging structure 290 over the second die 202 and/or the angle of the upward extending wire 1238 may be determined to achieve a desired length of the upward extending wire 1238. For example, the length of the wire connection 1238 may be reduced by decreasing the thickness of the packaging structure 290. The length of the wire connection 1238 may also be reduced by selecting the angle of the wire connection 1238 to align the wire 1238 perpendicularly to a surface of the packaging structure 290. Thus, such configurations having a wire connection 1238 with a reduced length may be particularly useful for acoustic device structures (e.g., acoustic device structures comprising one or more acoustic filter(s), multi-layer piezoelectric substrate acoustic wave filter(s), or integrated passive device(s)). In particular, such a wire connection 1238 of a decreased length may be particularly useful for providing a low inductance electrical path (e.g., to the ground).

The one or more electrodes of the packaging structure 290 may be positioned on the upper surface of the packaging structure 290 or may be embedded within the packaging structure 290 with a portion exposed on the upper surface of the packaging structure 290. Such configurations ensure that the electrodes are accessible from above the packaging structure 290, facilitating convenient electrical connections and enabling straightforward integration with other components.

Although the examples described above relate to the upwardly extending wire connection 1238, it will be appreciated that in other embodiments, an upwardly extending electrical connection 1238 may be provided in an alternative form. For example, the upwardly extending electrical connection 1238 may be provided in the form of a wall having conductive materials, extending through the thickness of the packaging structure 290. Such a wall having conductive materials may be provided by forming a cavity or passage (e.g., by drilling, milling, etching and/or lithography) in the packaging structure and subsequently depositing conductive materials, thereby creating a conductive wall that extends between the second die 202 and one or more electrodes of the packaging structure 290. Alternatively, such a cavity or passage may be completely or substantially filled to provide a conductive wire, rod, or bar extending through the thickness of the packaging structure 290.

The packaging structure 290 may be implemented in a number of forms to accommodate various design requirements. For example, the packaging structure 290 may at least partially encapsulate only the second die 202, or may at least partially encapsulate both the second die 202 and the first die 201. In some configurations, the packaging structure 290 may include a filler portion 370 that substantially fills the space surrounding the multi-stack acoustic wave device. Alternatively, the packaging structure 290 may include an air gap or cavity surrounded by an outer packaging 372 and the multi-stack die, depending on the desired design requirements. In embodiments in which there is an air gap or cavity between the packaging structure 290 and the multi-stack die, a combination of an upwardly extending wire 1238 and a conductive wall, wire, rod, or bar may be used to provide an electrical connection extending between the second die 202 and one or more electrodes of the packaging structure 290.

The bond wire(s) may be formed by using one or more wire bonding techniques. For example, forward or reverse wire bonding techniques may be used to form one or more of the bond wire(s). The forward bonding technique may involve first forming a ball bond on the die, followed by creating a stitch bond on one of the electrodes of the substrate. In contrast, the reverse bonding technique may involve first forming a bump on the die, followed by creating a ball bond on one of the electrodes of the substrate and subsequently forming a stitch bond on the bump.

As shown in FIG. 3C, the forward bonding technique may introduce a loop height constraint due to the neck region above the ball bond. In implementations where such a high loop height is not desirable, the reverse bonding technique, as illustrated in FIG. 3D, may provide a solution by enabling a lower loop height. The loop heights depicted in FIG. 3C (60 μm) and FIG. 3D (20 μm) demonstrate this contrast.

However, while the reverse bonding technique may enable a lower loop height, it may introduce a constraint in the form of an increased lateral keepout zone as illustrated in FIG. 3D, due to the wire arcing outward from the substrate to the die, resulting in a wider lateral spread compared to the forward bonding technique. The lateral widths illustrated in FIGS. 3C and 3D demonstrate this contrast, with reverse bonding utilizing a larger clearance around the wire trajectory near the substrate pads. Thus, in implementations in which a smaller keepout zone is desired, the forward bonding technique may be preferable. However, it will be appreciated that the examples discussed above are provided for illustrative purposes, and the dimensions, such as loop height, lateral keepout, and the angles of the bonding wires, may vary depending on the specific techniques used and the design.

FIGS. 3C and 3D also illustrate additional electrical components 1252, 1254 that may be mounted on the substrate.

As shown in the examples of FIG. 3A and FIG. 5, the multi-stack die may be formed by mounting the second die 202 on the first die 201. The mounting may be performed by joining the second portion of the first die 201 and the second portion of the second die 202 via a bonding layer 205, such as a die attach film. Alternatively, or in conjunction with the bonding layer 205, filler or packaging material(s) 290, 340 may be deposited to surround the multi-stack die to enhance the structural stability of the multi-stack die. Optionally, such filler or packaging material(s) 290, 340 may be deposited after the wire bonding has been completed to simplify the manufacturing process and/or to enhance the structural stability of the bonding wire 238.

The one or more first electrodes 218, 220 of the substrate 203 may be connected to one or more electrical connections within the substrate 203. Similarly, the one or more second electrodes 240 of the substrate 203 may be connected to one or more electrical connections within the substrate 203.

It will be appreciated that the one or more acoustic wave device components may include: one or more resonator structures, one or more bulk acoustic wave device components, one or more film bulk acoustic resonator components, one or more solidly mounted resonator components, one or more surface acoustic wave device components, one or more electrical connections and/or electrodes, and/or one or more cavity packages.

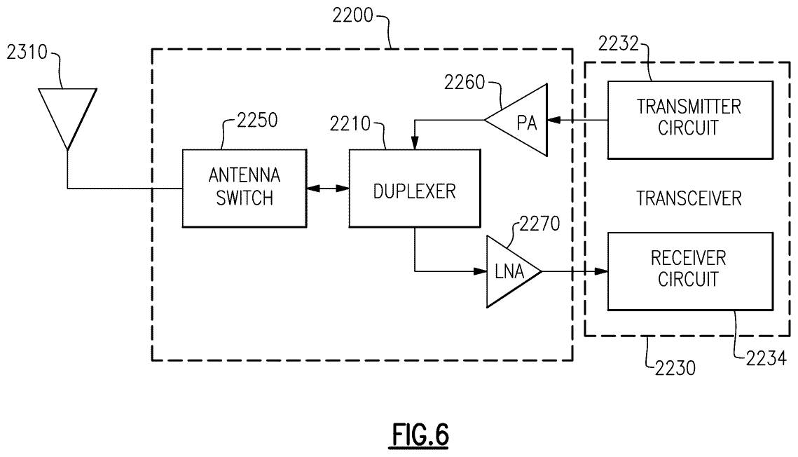

The multi-stack die shown in FIG. 3A or FIG. 5, or the acoustic device such as that of FIG. 4 or FIG. 5, may also be included in a radio-frequency front end (RFFE) module. An exemplary RFFE module is shown in FIG. 6. This figure illustrates a front-end module 2200, connected between an antenna 2310 and a transceiver 2230. The front-end module 2200 includes a duplexer 2210 in communication with an antenna switch 2250, which itself is in communication with the antenna 2310.

As illustrated, the transceiver 2230 comprises a transmitter circuit 2232. Signals generated for transmission by the transmitter circuit 2232 are received by a power amplifier (PA) module 2260 within the front-end module 2200 which amplifies the generated signals from the transceiver 2230. The PA module 2260 can include one or more PAs. The PA module 2260 can be used to amplify a wide variety of RF or other frequency-band transmission signals. For example, the PA module 2260 can receive an enable signal that can be used to pulse the output of the PA module 2260 to aid in transmitting a wireless local area network (WLAN) signal or any other suitable pulsed signal. The PA module 2260 can be configured to amplify any of a variety of types of signals, including, for example, a Global System for Mobile (GSM) signal, a code division multiple access (CDMA) signal, a W-CDMA signal, a Long-Term Evolution (LTE) signal, or an EDGE signal.

In certain embodiments, the PA module 2260 and associated components including switches and the like can be fabricated on gallium arsenide (GaAs) substrates using, for example, high electron mobility transistors (pHEMT) or insulated-gate bipolar transistors (BiFET), or on a silicon substrate using complementary metal-oxide semiconductor (CMOS) field effect transistors (FETs).

Still referring to FIG. 6, the front-end module 2200 may further include a low noise amplifier (LNA) module 2270, which amplifies received signals from the antenna 2310 and provides the amplified signals to the receiver circuit 2234 of the transceiver 2230.

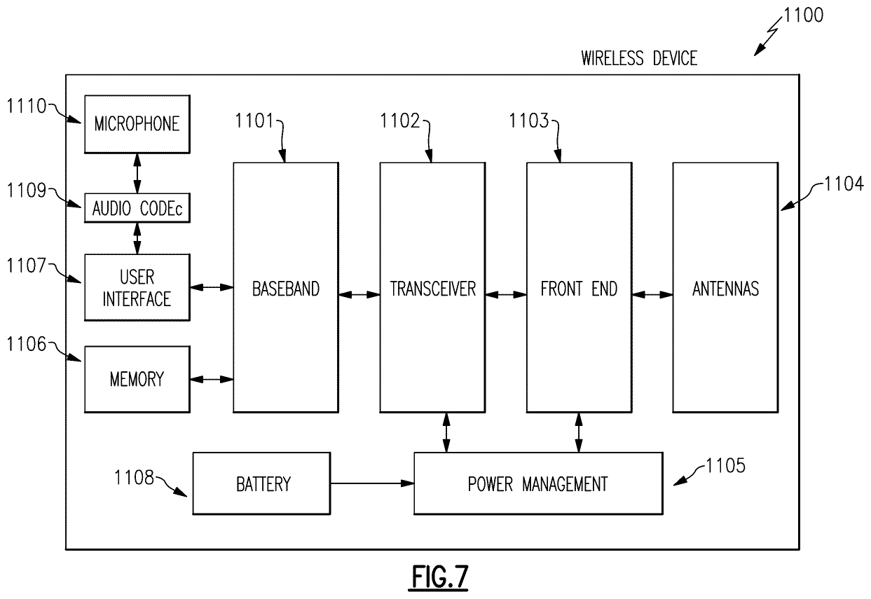

FIG. 7 is a schematic diagram of a wireless device 1100 that can incorporate aspects and embodiments disclosed herein. The wireless device 1100 can be, for example, but not limited to, a portable telecommunication device such as a mobile cellular-type telephone. The wireless device 1100 can include a microphone arrangement 1110, and may include one or more of a baseband system 1101, a transceiver 1102, a front-end system 1103 (such as the front-end module 2200 of 6 6), one or more antennas 1104, a power management system 1105, a memory 1106, a user interface 1107, a battery 1108, and audio codec 1109. The microphone arrangement 1110 may supply signals to the audio codec 1109 which may encode analog audio as digital signals or decode digital signals to analog. The audio codec 1109 may transmit the signals to a user interface 1107. The user interface 1107 transmits signals to the baseband system 1101. The transceiver 1102 generates RF signals for transmission and processes incoming RF signals received from the antennas 1104. The front-end system 1103 aids in conditioning signals transmitted to and/or received from the antennas 1104. The antennas 1104 can include antennas used for a wide variety of types of communications. For example, the antennas 1104 can include antennas 1104 for transmitting and/or receiving signals associated with a wide variety of frequencies and communications standards. The baseband system 1101 is coupled to the user interface to facilitate processing of various user input and output, such as voice and data. The baseband system 1101 provides the transceiver 1102 with digital representations of transmit signals, which the transceiver 1102 processes to generate RF signals for transmission. The baseband system 1101 also processes digital representations of received signals provided by the transceiver 1102.

As shown in FIG. 7, the baseband system 1101 is coupled to the memory 1106 to facilitate operation of the wireless device 1100. The memory 1106 can be used for a wide variety of purposes, such as storing data and/or instructions to facilitate the operation of the wireless device 1100 and/or to provide storage of user information. The power management system 1105 provides a number of power management functions of the wireless device 1100. The power management system 1105 receives a battery voltage from the battery 1108. The battery 1108 can be any suitable battery for use in the wireless device, including, for example, a lithium-ion battery.

Having described above several aspects of at least one embodiment, it is to be appreciated various alterations, modifications, and improvements will readily occur to those skilled in the art. Such alterations, modifications, and improvements are intended to be part of this disclosure and are intended to be within the scope of the aspects and embodiments disclosed herein. Accordingly, the foregoing description and drawings are by way of example only, and the scope of the aspects and embodiments disclosed herein should be determined from proper construction of the appended claims, and their equivalents.

What is claimed is:

1. A multi-stack acoustic wave device comprising:
a substrate having one or more electrodes;
a first die having a first portion having one or more electrodes and a second portion positioned away from the first portion, the one or more electrodes of the first die being coupled to and electrically connected with the one or more electrodes of the substrate;
a second die having a first portion having one or more electrodes and a second portion positioned away from the first portion, the first die being positioned between the second die and the substrate, and the second portion of the first die being coupled to the second portion of the second die; and
a packaging structure encapsulating at least a portion of the second die, the packaging structure having one or more electrodes positioned away from the substrate, the one or more electrodes of the second die being electrically connected to the one or more electrodes of the packaging structure via one or more electrical connections.

2. The multi-stack acoustic wave device of claim 1 wherein the one or more electrical connections electrically connecting the one or more electrodes of the second die to the one or more electrodes of the packaging structure are provided in form(s) of bonding wire(s).

3. The multi-stack acoustic wave device of claim 1 wherein the one or more electrical connections electrically connecting the one or more electrodes of the second die to the one or more electrodes of the packaging structure are provided in form(s) of via(s).

4. The multi-stack acoustic wave device of claim 1 wherein the one or more electrodes of the first die are directly coupled to the one or more electrodes of the substrate.

5. The multi-stack acoustic wave device of claim 1 wherein the one or more electrodes of the first die are coupled to the one or more electrodes of the substrate via one or more conductive layers.

6. The multi-stack acoustic wave device of claim 1 wherein the one or more electrodes of the first die comprise a portion that is at least partially embedded in the first portion of the first die.

7. The multi-stack acoustic wave device of claim 6 wherein the one or more electrodes of the first die comprise a portion extending through a thickness of the first portion of the first die forming an electrical path connecting to the second portion of the first die.

8. The multi-stack acoustic wave device of claim 1 wherein the first die is an acoustic wave filter.

9. The multi-stack acoustic wave device of claim 1 wherein the one or more electrodes of the second die comprise a portion that is at least partially embedded in the first portion of the second die.

10. The multi-stack acoustic wave device of claim 9 wherein the one or more electrodes of the second die comprise a via extending through a thickness of the first portion of the second die forming an electrical path connecting to the second portion of the second die;

11. The multi-stack acoustic wave device of claim 1 wherein the one or more electrodes of the second die are positioned between the first portion and the second portion of the second die.

12. The multi-stack acoustic wave device of claim 1 wherein the second die is an acoustic wave filter.

13. The multi-stack acoustic wave device of claim 1 wherein the second die is an integrated passive device.

14. The multi-stack acoustic wave device of claim 1 wherein the second die is a multi-layer piezoelectric substrate acoustic wave filter.

15. The multi-stack acoustic wave device of claim 1 wherein the second portion of the first die is coupled to the second portion of the second die via a bonding layer.

16. The multi-stack acoustic wave device of claim 1 wherein the substrate is one of a laminate substrate, a printed circuit board, or a ceramic substrate.

17. The multi-stack acoustic wave device of claim 1 wherein the one or more electrodes are connected to one or more electrical connections within the substrate.

18. The multi-stack acoustic wave device of claim 1 wherein the one or more electrodes of the packaging structure are connected to one or more electrical connections within the packaging structure.

19. A radio-frequency module comprising a multi-stack acoustic wave device having:
a substrate having one or more electrodes;
a first die having a first portion having one or more electrodes and a second portion positioned away from the first portion, the one or more electrodes of the first die being coupled to and electrically connected with the one or more electrodes of the substrate;
a second die having a first portion having one or more electrodes and a second portion positioned away from the first portion, the first die being positioned between the second die and the substrate, and the second portion of the first die being coupled to the second portion of the second die; and
a packaging structure encapsulating at least a portion of the second die having one or more electrodes positioned away from the substrate, the one or more electrodes of the second die being electrically connected with the one or more electrodes of the packaging structure via one or more electrical connections.

20. A wireless mobile device comprising:
one or more antennas; and
a radio-frequency module that communicates with the one or more antennas, the radio-frequency module including a multi-stack acoustic wave device having a substrate having one or more electrodes, a first die having a first portion having one or more electrodes and a second portion positioned away from the first portion, the one or more electrodes of the first die being coupled to and electrically connected with the one or more electrodes of the substrate, a second die having a first portion having one or more electrodes and a second portion positioned away from the first portion, the first die being positioned between the second die and the substrate, and the second portion of the first die being coupled to the second portion of the second die, and a packaging structure encapsulating at least a portion of the second die having one or more electrodes positioned away from the substrate, the one or more electrodes of the second die being electrically connected with the one or more electrodes of the packaging structure via one or more electrical connections.
